(19) United States
(12) Patent Application Publication
(10) Pub. No.: US 2023/0197558 A1
(43) Pub. Date: Jun. 22, 2023

(54) LIQUID METAL PASTE CONTAINING METAL PARTICLE ADDITIVE

(71) Applicant: Indium Corporation, Utica, NY (US)

(72) Inventors: Guangyu Fan, Deerfield, NY (US); Ross Berntson, New Hartford, NY (US)

(21) Appl. No.: 18/086,345

(22) Filed: Dec. 21, 2022

Related U.S. Application Data
(60) Provisional application No. 63/292,996, filed on Dec. 22, 2021.

(51) Int. Cl. H01L 23/373; B22F 1/16; H01L 23/42

(52) U.S. Cl. CPC H01L 23/3736; B22F 1/16; H01L 23/42

(57) ABSTRACT

Some implementations of the disclosure are directed to liquid metal pastes that can be used as thermal interface materials. In one implementation, a liquid metal paste configured to be applied as a thermal interface material between electronic components, includes: 92.5 wt % of 99.9 wt % of a liquid gallium or liquid gallium alloy; and 0.1 wt % to 7.5 wt % of a powder of metal particles, the metal particles including Ag, Au, Cu, W, Ti, Cr, Ni, Cu or Ni. The liquid metal paste can also include an organic compound coating a surface of the metal particles, the organic compound configured to prevent the metal particles from forming an intermetallic compound with the liquid gallium or liquid gallium alloy.

### CROSS-REFERENCE TO RELATED APPLICATIONS

This application claims priority to U.S. Provisional Patent Application No. 63/292,996, titled “LIQUID METAL PASTE CONTAINING METAL PARTICLE ADDITIVE” filed Dec. 22, 2021, which is incorporated herein by reference in its entirety.

### DESCRIPTION OF THE RELATED ART

Heat dissipation is a key factor in the longevity and reliability of semiconductor and power devices. To improve thermal performance, electronic assemblies may provide thermal management via a thermal interface material (TIM) that minimizes thermal resistance between a heat generating device/source (e.g., microprocessor) and a heat transferring device.

TIMs that have been widely used in electronic devices include thermal greases or pastes, pads, phase-changing materials, and adhesives. Most of these TIMs are polymer-based composites with metal or ceramic conductive particle fillers. For example, thermal grease is a commonly used TIM with thermal contact resistances typically in the range of 0.2 to 1.0 cm² K/W. The thermal contact resistance can be reduced to 0.053 cm² K/W by mixing polyethylene glycol with boron nitride. However, there are drawbacks to using thermal greases as TIMs. Greases are messy and challenging to apply and rework, and have reliability issues relating to pump out, phase separations, and dry-out. For example, the powering up and down of electronic devices causes a relative motion between the die and the heat-spreader due to their different coefficients of thermal expansion, which can tend to “pump” out the thermal grease from the interface gap. As such, although thermal greases may provide good thermal performance upon installation, upon extended use and over time, these greases can degrade, resulting in higher thermal resistance at the interface. This limits the use of grease as an efficient TIM over an electronic device's nominal lifespan of operation.

Solder is another type of TIM that has been widely used due to the higher thermal conductivity and the low contact thermal resistance (e.g., below 0.05 cm² K/W) of some solders. For example, the thermal resistance of Sn—Bi solder paste is less than 0.05 cm² K/W. It also has good reliability, which would potentially make it a promising TIM candidate for power electronics applications. However, Sn—Bi solder paste has poor rework ability, and it requires high processing temperatures that could cause void formation and thermal stress evolving into the electronic components.

As such, with the growth of faster, more powerful devices, there is a need for improved TIMs.

### BRIEF SUMMARY OF THE DISCLOSURE

Some implementations of the disclosure are directed to a liquid metal paste (LMP) that can be used as a thermal interface material. The liquid metal paste includes a liquid metal or liquid metal alloy, a powder of metal particles, and, optionally, one or more organic compounds coating the metal particles. The liquid metal paste can be particularly suited for printing on a substrate during semiconductor assembly.

In one embodiment, a liquid metal paste configured to be applied as a thermal interface material between electronic components, comprises: 92.5 wt % of 99.9 wt % of a liquid gallium or liquid gallium alloy; and 0.1 wt % to 7.5 wt % of a powder of metal particles, the metal particles comprising Ag, Au, Cu, W, Ti, Cr, Ni, Cu or Ni.

In some implementations, the particles comprise Ag, Au, Cu, or Ni.

In some implementations, the liquid metal paste comprises 92.5 wt % to 99.9 wt % of the liquid gallium or liquid gallium alloy; and 0.1 wt % to 5.0 wt % of the powder of the metal particles, the metal particles comprising Ag or Cu particles.

In some implementations, the metal particles comprise Ag.

In some implementations, the liquid metal paste comprises: 92.5 wt % to 99.9 wt % of the liquid gallium or liquid gallium alloy; and 0.1 wt % to 1.5 wt % of the powder of the metal particles, the metal particles consisting of Ag particles.

In some implementations, the liquid metal paste consists of: 98.5 wt % to 99.9 wt % of the liquid gallium or liquid gallium alloy; and 0.1 wt % to 1.5 wt % of the powder of metal particles.

In some implementations, the liquid gallium alloy is: 64 wt % to 69 wt % Ga, 19 wt % to 22 wt % In, and 10 wt % to 16 wt % Sn; 75 wt % to 80 wt % Ga, and 20 wt % to 25 wt % In; or 67 wt % to 73 wt % Ga, 18 wt % to 22 wt % In, 7 wt % to 9 wt % Sn, and 1 wt % to 3 wt % Zn.

In some implementations, the liquid gallium alloy is 66.5Ga20.5In13.0Sn, 78.6Ga21.4In, or 70Ga20In8Sn2Zn.

In some implementations, the liquid metal paste includes 92.5 wt % to 99.9 wt % of the liquid gallium alloy, the liquid gallium alloy comprising GaIn, GaSn, GaInSn, or GaInSnZn.

In some implementations, the liquid gallium alloy comprises eutectic GaIn or eutectic GaInSn.

In some implementations, the liquid metal paste further comprises: an organic compound coating a surface of the metal particles, the organic compound configured to prevent the metal particles from forming an intermetallic compound with the liquid gallium or liquid gallium alloy.

In some implementations, the organic compound comprises a hydrocarbon compound containing fluoride, ethoxy, methoxy, ketone, or an ester group.

In some implementations, the organic compound comprises a trimethoxy or trichloro silane containing short chain hydrocarbon (C2 to C6) with fluoride, ethoxy, methoxy, ketone, glycidyloxy, or an ester group.

In some implementations, the organic compound comprises:

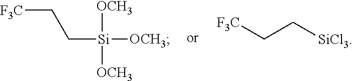

In some implementations, the liquid metal paste comprises: 92.5 wt % to 99.8 wt % of the liquid gallium or liquid gallium alloy; 0.1 wt % to 5.0 wt % of the powder of the metal particles, the metal particles comprising Ag or Cu particles; and the organic compound coating the surface of the Ag or Cu particles, the organic compound configured to prevent the Ag or Cu particles from forming the intermetallic compound with the liquid gallium or liquid gallium alloy.

In some implementations, the metal particles are spherical particles. In some implementations, the metal particles have a diameter between about 5 μm and 50 μm.

In one embodiment, an assembly comprises: a heat generating device; a heat transferring device; and a thermal interface between surfaces of the heat generating device and heat transferring device, wherein the thermal interface is formed by applying a liquid metal paste comprising: 92.5 wt % to 99.9 wt % of a liquid gallium or liquid gallium alloy; 0.1 wt % to 7.5 wt % of a powder of metal particles, the metal particles comprising Ag, Au, Cu, W, Ti, Cr, Ni, Cu or Ni; and optionally, an organic compound coating a surface of the metal particles.

In some implementations, the heat generating device is a semiconductor die, and the heat transferring device is a semiconductor package lid.

In some implementations, the heat generating device is a semiconductor die, and the heat transferring device is a heat sink.

In one embodiment, a method comprises: applying a liquid metal paste between a heat generating device and a heat transferring device to form an assembly having the liquid metal paste in touching relation with a surface of the heat generating device, or in touching relation with a surface of the heat transferring device, the liquid metal paste comprising 92.5 wt % to 99.9 wt % of a liquid gallium or liquid gallium alloy; 0.1 wt % to 7.5 wt % of a powder of metal particles, the metal particles comprising Ag, Au, Cu, W, Ti, Cr, Ni, Cu or Ni; and optionally, an organic compound coating a surface of the metal particles, wherein the liquid metal paste acts as a thermal interface material configured to transfer heat from the heat generating device to the heat transferring device.

In some implementations, the method further includes forming the thermal interface material from the liquid metal paste by processing the liquid metal paste. In some implementations, processing the liquid metal paste includes heating the liquid metal paste (e.g., by the heat generating device).

In some implementations, applying the liquid metal paste between the heat generating device and the heat transferring device, comprises: printing the liquid metal paste onto the surface of the heat generating device or the surface of the heat transferring device.

In one embodiment, a method for forming a liquid metal paste, comprises: adding a powder of metal particles to liquid gallium or a liquid gallium alloy in a container to form a mixture; and mechanically stirring the mixture for 40 minutes or less to form the liquid metal paste. In other implementations, the mixture can be mechanically stirred for 50 minutes or less, 60 minutes or less, or more than 60 minutes.

Other features and aspects of the disclosed technology will become apparent from the following detailed description, taken in conjunction with the accompanying drawings, which illustrate, by way of example, the features in accordance with implementations of the disclosed technology. The summary is not intended to limit the scope of any inventions described herein, which are defined by the claims and equivalents.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

The present disclosure, in accordance with one or more implementations, is described in detail with reference to the following figures. The figures are provided for purposes of illustration only and merely depict example implementations. Furthermore, it should be noted that for clarity and ease of illustration, the elements in the figures have not necessarily been drawn to scale.

FIG. 1 shows a semiconductor assembly including a TIM formed from a liquid metal paste, in accordance with some implementations of the disclosure.

FIG. 2 shows another semiconductor assembly including TIMs formed from liquid metal pastes, in accordance with some implementations of the disclosure.

FIG. 3 shows an image of a LMP after being printed on a Si chip.

FIG. 4 shows an image of the LMP of FIG. 3 after a glass slide is applied on top of the assembly.

FIG. 5 shows an image of a LMP, including Ag metal particles, pressed between two glass slides.

FIG. 6A shows an image of a liquid metal paste after preparation.

FIG. 6B shows an image of a liquid metal paste after preparation.

FIG. 6C shows an image of a liquid metal paste after preparation.

FIG. 6D shows an image of a liquid metal paste after preparation.

FIG. 6E shows an image of a liquid metal paste after preparation.

FIG. 7 is a chemical reaction formula showing (3-Fluropropyl) trimethoxy silane reacting with a hydroxy-group on the surface of a Ag particle to form a silicon oxide bond with a 3-Fluoropropyl group.

FIG. 8 shows a crystal structure of gallium oxide at the interface between a gallium liquid metal alloy and Ag particles, and the interaction with an Ag particle containing an organic capping agent.

FIG. 9 shows a linear fit plot of thermal impedance (θ) of a sample as a function of sample thickness.

FIG. 10 shows a plot depicting thermal resistance as a function of input power for different TIM samples, including some LMPs in accordance with the disclosure.

FIG. 11 shows a plot depicting thermal resistance as a function of thermal cycles for different TIM samples, including some LMPs in accordance with the disclosure.

FIG. 12 is a plot showing the measured thermal properties of LMP samples comprised of 66.5Ga20.5In13Sn with 1 wt % of Ag, in accordance with some implementations of the disclosure.

FIG. 13 is a plot showing the measured thermal properties of LMP samples comprised of 78.6Ga21.4In with 1 wt % of Ag, in accordance with some implementations of the disclosure.

The figures are not exhaustive and do not limit the disclosure to the precise form disclosed.

### DETAILED DESCRIPTION OF THE EMBODIMENTS

Recently, liquid metal and liquid metal alloys such as Ga, GaIn, GaInSn have drawn attention for potential use as TIMs because of their high heat transfer capacity, good thermal conductivity, and very low contact thermal resistance. For example, a research group recently reported low melting temperature alloys containing gallium (Ga), indium (In), bismuth (Bi) and tin (Sn) had a thermal contact resistance as low as 0.005 cm² K/W, which is much lower than that of polymer-based thermal greases. Despite liquid metal alloys having low thermal interface resistances, Ga-based TIMs have several issues, including: oxidation/corrosion, intermetallic growth, dry-out, and dewetting after the oxidation of most of Ga in the alloys that would increase interfacial thermal resistance. Various methods to mitigate these problems have been proposed. For example, the oxidation of liquid metal alloys may be minimized by a hermetic seal, and the formation of intermetallic compounds may be prevented by applying a diffusion barrier coating like a nickel layer. In one experiment, it was reported that the use of a gasket sealant could reduce the oxidation of liquid metal alloys significantly. However, Ga-based TIMs have poor wettability and adhesion to Si, Cu and other surface finish substrates based on traditional deposition processes such as printing and dispensing using surface mount equipment in the electronics industry.

Thus, there is a need for developing liquid metal alloys having good wettability and adhesion on silicon, bare copper, Ni-plated, and/or Au-plated substrates. There is also a need for developing liquid metal alloys that exhibit excellent automation process performance (i.e., dispensing of the liquid metal on a substrate). There is a further need for developing liquid metal alloys that provide good thermal conductivity and well-suited for controlling bond line thickness (BLT) as a thermal interface material.

To this end, the disclosure is directed to a Ga-based liquid metal or metal alloy paste containing a low content of metal particles such as silver (Ag). Various advantages may be realized by forming a liquid metal paste containing a low content of metal particles as descried herein. First, the addition of the metal particles may facilitate the formation of the composite liquid metal and metal particles into a paste. Second, the presence of the metal particles enables a thermal interface material having controllable BLT. Additionally, the addition of the metal particles may improve thermal performance of a TIM formed from the paste, helping provide thermal management of an integrated circuit package. For example, the TIM may function as a high performance TIM for the cooling of a microprocessor IC package such as a CPU, GPU, HPC, etc.

In some implementations, further described below, the metal particles of the paste may be coated with one or more organic compounds. The coating of the one or more organic compounds may enhance compatibility of the liquid metal and metal particles. The coating may be helpful in homogeneously dispersing metal particles in a matrix of liquid metal and oxide composition due to Van der Waals forces, and preventing the metal particles from forming intermetallic compounds (IMC) with the Ga element in the liquid metal alloy.

The liquid metal paste as described herein may also allow for consistent printing on bare Cu PCB, good adhesion on bare Cu PCB, good adhesion on OSP FR4 coupons, and/or good adhesion on glass. Moreover, it may provide for excellent wetting on non-metallized surfaces such as glass and silicon.

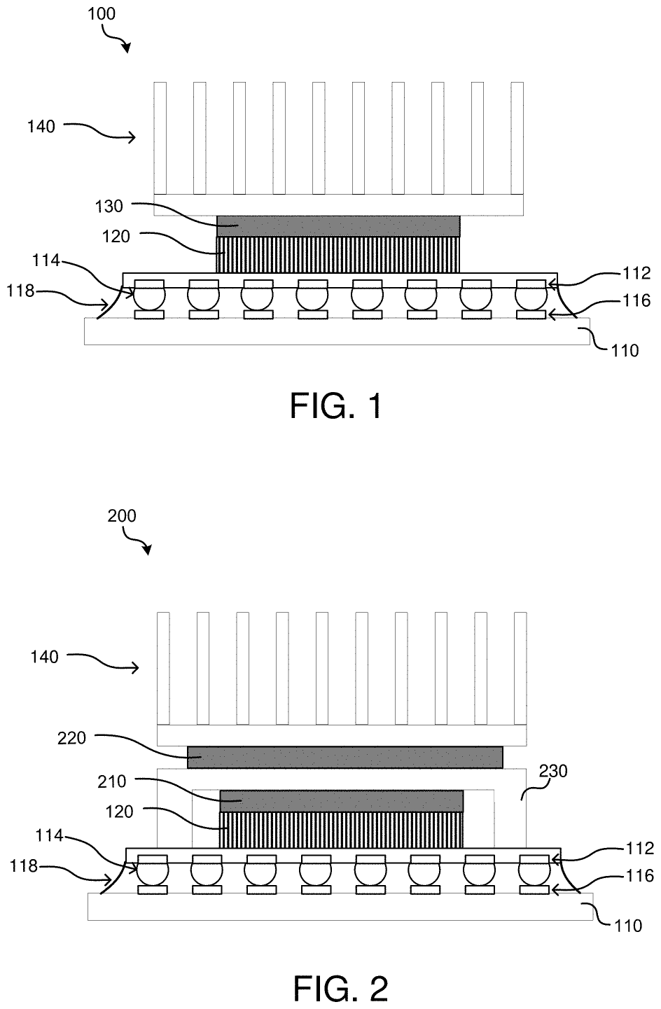

FIG. 1 shows a semiconductor assembly 100 including a TIM 130 formed from a liquid metal paste in accordance with implementations of the disclosure. In this example and other semiconductor assembly examples illustrated in the figures, the TIMs are used in a chip carrier depicted as a ball grid array (BGA) assembly. However, it should be appreciated that the TIMs may be utilized to provide a TIM in other semiconductor assemblies, chip carriers, or surface-mount packaging, including, for example, land grid arrays (LGA), pin grid arrays (PGA), and the like.

Semiconductor assembly 100 includes PCB 110, semiconductor die 120, liquid metal paste TIM 130, and heat sink 140. The semiconductor die 120 is mounted to PCB 110. Solder spheres 114 were placed on metallized pads 112 of the semiconductor die 120 and reflowed to electrically connect metallized pads 112 to the electrical connectors 116 of the PCB 110. In this manner, electrical signals may be conducted between the semiconductor die 120 and the circuit board 110 onto which the assembly is placed. 118 illustrates an underfill applied between the semiconductor die 120 and circuit board 110.

TIM 130 is configured to transfer heat generated by semiconductor die 120 to heat sink 140. In this arrangement in which TIM 130 is the thermal interface material between the semiconductor die 120 and heat sink 140, TIM 130 may be referred to as a TIMO thermal interface material.

As further discussed below, TIM 130 may be formed from a liquid metal paste containing solid metal particles that are optionally coated with one or more organic agents. The paste may be prepared via in-situ oxidation of the gallium element in the liquid metal alloy mixed with a powder containing metal particles.

FIG. 2 shows a semiconductor assembly 200 including a liquid metal paste TIM 210 and liquid metal paste TIM 220 in accordance with implementations of the disclosure. In this implementation, semiconductor package lid or heat spreader 230 is configured to transfer energy as heat from die 120, via TIM 210, to heat sink 140, via TIM 220.

TIM 210 is configured to transfer heat generated by semiconductor die 120 to lid 230. In this arrangement in which TIM 210 is the thermal interface material between the semiconductor die 120 and lid 230, TIM 210 may be referred to as a TIM1 thermal interface material.

TIM 220 is configured to transfer heat from lid 230 to heat sink 140. In this arrangement in which TIM 220 is the thermal interface material between the semiconductor package lid 230 and heat sink 140, TIM 220 may be referred to as a TIM2 thermal interface material.

The composition of each of TIM 210 and TIM 220 may be similar to that of TIM 130 described above, and further elaborated on below.

The liquid metal paste may be applied to the device thermal stack up to form TIM 130, TIM 210, or TIM 220. The liquid metal paste can be printed onto the surface(s) of the heat spreader/cold plate or heat sink 140, semiconductor package lid 230, and/or bare Si semiconductor die backside 120. For example, it may be printed on a surface over die 120 or lid 230. Advantageously, the liquid metal paste described herein may be printed using a printer such as MPM Momentum II 100 or DEK Horizon 031X printer. As such, the liquid metal paste may be helpful to enhance automation processes like printing processes using standard printers in the surface mount technology and semiconductor industries. In some cases, a dam or sealant may be used to confine the liquid metal paste between components. For TIM 1 applications, the assembly packaging may include an adhesive bonding lid or other suitable bonding mechanism. For TIM 2 or TIM 0 applications, the heat sink may be fastened to the assembly by bolts or using some other suitable bonding mechanism.

The liquid metal pastes described herein may be in a paste form at room temperature, and after applying as TIM (TIM1, TIM2 or TIMO) between heat source and heat sink, have an operational temperature range from −40° C. to 125° C., where the operational temperature range refers to a temperature range in which the TIM remains stable and functions during operation of the electronic assembly.

The liquid metal or liquid metal alloy of the liquid metal paste may include gallium; gallium alloys; a combination of gallium and indium; a combination of gallium, indium, and tin; a combination of gallium indium, tin, and zinc; mixtures thereof; or other suitable liquid metals or metal alloys. For example, it may include a gallium alloy such as GaIn, GaSn, GaInSn, or GaInSnZn, and the gallium alloy may be eutectic. For example, the eutectic gallium alloy may be EGaIn or EGaInSn (e.g., Galinstan). The liquid metal or liquid metal alloy can have a low melting temperature, e.g., below 30° C. or room temperature.

The metal particles added to the liquid metal paste may be a solid metal particle powder such as a powder of Ag, Au, Cu, W, Ti, Cr, Ni, Cu and/or Ni. More preferably, the metal particles may comprise Ag, Au, Cu, or Ni. Even more preferably, the metal particles may comprise Ag, Cu, or Au. The content of the metal particles in the liquid metal paste may range from about 0.1 wt % to 7.5 wt %. In particular implementations, the content of the metal particles in the liquid metal paste may range from about 0.1 wt % to 1.5 wt %. The metal particles may be spherical particles having a diameter between about 5 μm and 50 μm. The size of the metal particles may be chosen to achieve a desired BLT when the liquid metal paste is formed into a TIM.

As discussed above, the liquid metal paste may be prepared from in-situ oxidation of the gallium element in the liquid metal alloy mixed with the metal particles. For the purpose of improving compatibility of the metal powder with the oxide generated from the liquid metal, the metal powder may be coated with one or more organic agents such as agents containing C2 to C6 hydrocarbon compounds. The formed composition may take the form of a micro or nano structural gallium oxide framework containing metal additives to hold liquid metal and/or liquid metal alloys. In some implementations, the use of EGaIn, EGaInSn or GaInSnZn may be preferable to preparing the liquid metal paste by in-situ oxidation of the gallium element.

In some implementations, the metal particles may be coated with organic capping agents/compounds to stabilize dispersion in a matrix of liquid metal and gallium oxide composition. For example, the organic capping agents may be hydrocarbon compounds containing fluoride, ethoxy, methoxy, ketone, and/or an ester group. More preferably, the organic capping agents may utilize trimethoxy or trichloro silane containing short chain hydrocarbon (C2 to C6) with fluoride element, ethoxy, methoxy, ketone, glycidyloxy and/or an ester group.

In some implementations, the content of the organic capping agents in the liquid metal paste may range from about 0.1 wt % to 0.5 wt %.

The organic capping compounds may preferably have a strong affinity to gallium oxide via Van der Waals forces, and prevent metal particles from forming IMC with liquid metal alloys and precipitating from the matrix of liquid metal alloy and oxide composition.

As an example, in a particular implementation, the organic capping agents include (3-Fluoropropyl) trimethoxy silane (C₆H₁₅FO₃Si), which can have a chemical structure as depicted below.

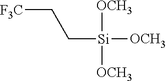 [SMILES: CO[Si](CCC(F)(F)F)(OC)OC]

In another particular example, the organic capping agents include (3-Fluoropropyl) trichloride silane, which can have a chemical structure as depicted below.

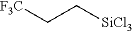

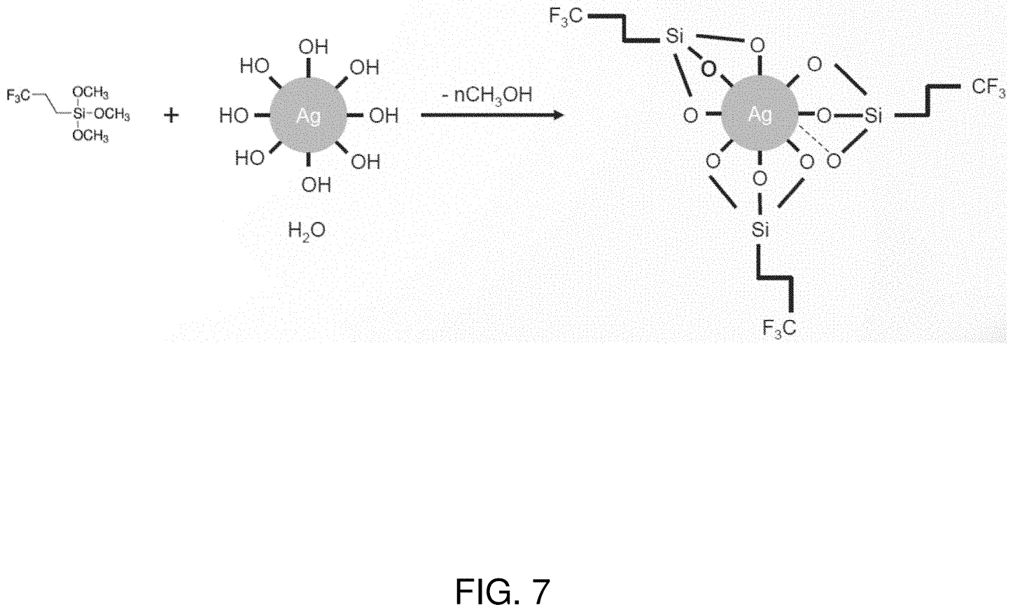

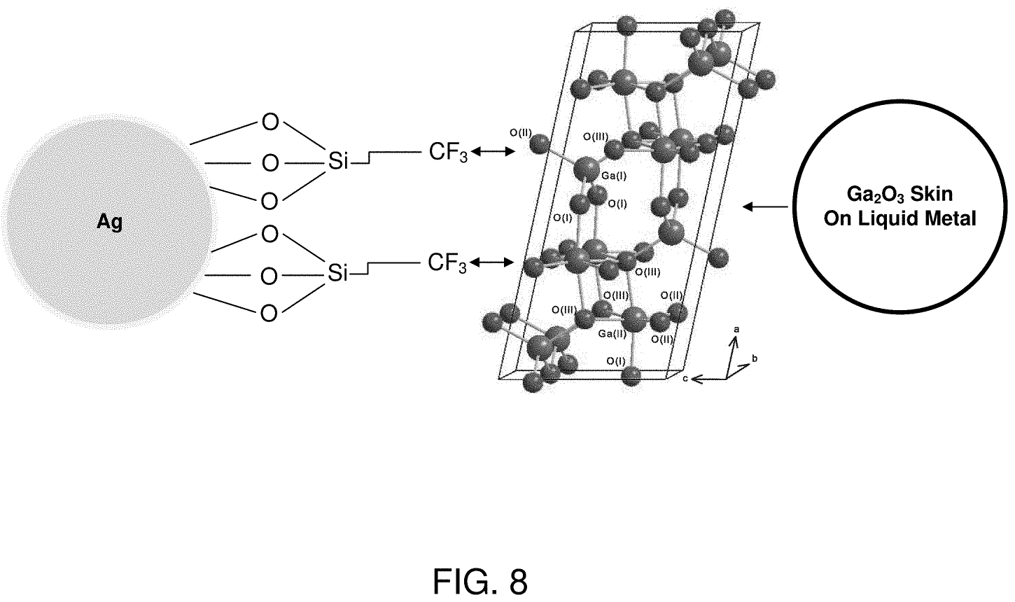

FIG. 7 is a chemical reaction formula showing (3-Fluropropyl) trimethoxy silane reacting with a hydroxy-group on the surface of a Ag particle to form a silicon oxide bond with a 3-Fluoropropyl group. FIG. 8 shows a crystal structure of gallium oxide at the interface between a gallium liquid metal alloy and Ag particles, and the interaction with an Ag particle containing an organic capping agent (e.g., as described by FIG. 7). In this case, the metal particles (e.g., Ag particles) with the capped agent could be dispensed into the liquid metal matrix well due to the existence of a trifluoro carbonyl group, and keep them from precipitation from the composites. In the meantime, it could enhance thermal conductivity and reduce interfacial resistance between the metal particle and gallium oxide because of the strong affinity of the fluoro group to gallium oxide.

As further described below, the liquid metal paste may be prepared via in-situ oxidation. In particular, the liquid metal particles (with or without organic compound coating) may be added to a gallium or gallium alloy liquid metal base, and mixture may be stirred (e.g., using a suitable mixing tool). The gallium element oxidizes, and the act of stirring the mixture disperses the oxide in the composite, and a paste forms. One advantage that was found was that the use of metal particle additives facilitated formation of the liquid metal paste, reducing the time it took to form the paste. It was further observed that liquid metal pastes formed in accordance with the disclosure exhibited good storage stability at ambient temperature and pressure, not showing any significant changes after months.

Experimental Results

Tests were conducted showing performance of liquid metal pastes in accordance with the disclosure.

In one example, a liquid metal paste LMP300EAg was prepared in situ by adding 99 g of 300E (78.6Ga21.4In) and 1 g of Ag particles to a beaker of 100 ml, and stirring the mixture under atmospheric pressure by a mechanical stirrer for an hour to form a liquid metal paste including Ag particles (LMP300EAg). The process was repeated by stirring 300E without adding Ag particles to form a paste consisting of gallium oxide and a liquid metal (LMP300E). In experiments, the effective thermal conductivity of this liquid metal paste containing 1 wt % of Ag particles was measured to be 8.55 W/m K or above, with thermal resistance of 0.0178 K/W and a bond line thickness (BLT) or thickness of 60 μm.

In another example, a liquid metal paste LMP51EAg was prepared in situ by adding 99 g of 51E (66.5Ga20.5In13Sn) and 1 g of Ag particles to a beaker of 100 ml, and stirring the mixture under atmospheric pressure by a mechanical stirrer for an hour to form a liquid metal paste include Ag particles (LMP51EAg). The process was repeated by stirring 51E without adding Ag particles to form a paste consisting of gallium oxide and a liquid metal (LMP51E). In experiments, the effective thermal conductivity of this liquid metal paste containing 1 wt % of Ag particles was measured to be 6.79 W/m K, with thermal resistance of 0.04 K/W and a thickness of 131 μm.

In a further example, a liquid metal paste LMP51ECu was prepared in situ by adding 99 g of 51E (66.5Ga20.5In13Sn) and 1 g of Cu particles to a beaker of 100 ml, and stirring the mixture under atmospheric pressure by a mechanical stirrer for an hour to form a liquid metal paste including Cu particles (LMP51ECu). The process was repeated by stirring 51E without adding Cu particles to form a paste consisting of gallium oxide and a liquid metal (LMP51E). In experiments, the effective thermal conductivity of this liquid metal paste containing 1 wt % of Cu particles was measured to be 3.78 W/m K, with thermal resistance of 0.087 K/W and a thickness of 149 μm.

In a further example, a liquid metal paste LMP2NAg was prepared in situ by adding 99 g of LM2N (70Ga20In8Sn2Zn) and 1g of Ag particles to a beaker of 100 ml, and stirring the mixture under atmospheric pressure by a mechanical stirrer for an hour to form a liquid metal paste including Ag particles (LMP2NAg). The process was repeated by stirring without adding Ag particles to form a paste consisting of gallium oxide and a liquid metal (LMP2N). In experiments, the effective thermal conductivity of this liquid metal paste containing 1 wt % of Ag particles was measured to be 9.19 W/m K, with thermal resistance of 0.05 K/W and a thickness of 205 μm.

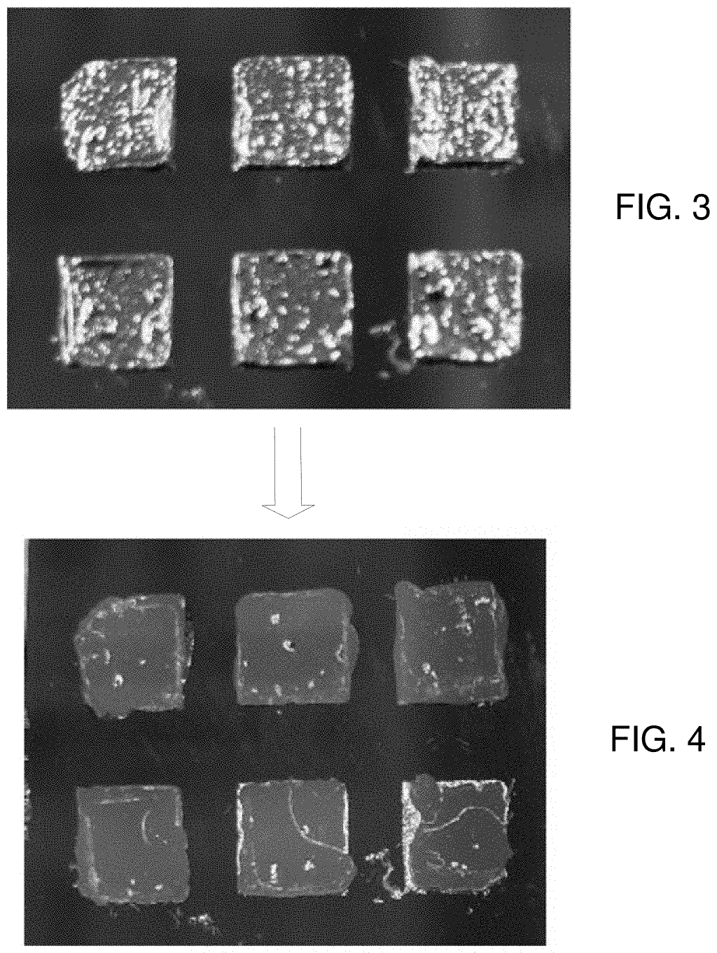

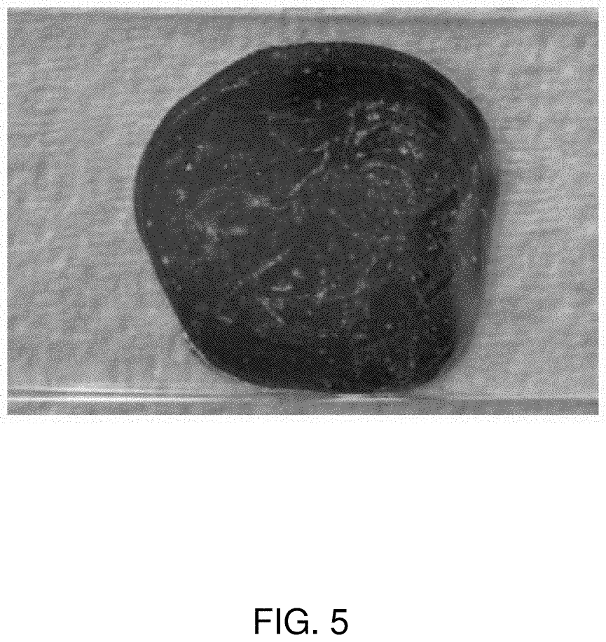

It was observed that in contrast to the stirred LMP300E, LMP300EAg did not squeeze out when pressed, indicating that the paste would be suitable for providing effective BLT as a TIM. Tests also indicated that both LMP300E and LMP300EAg provided good adhesion on bare Si and glass, and excellent wetting on Si and glass. These advantages (good adhesion and wetting, and no squeezing out) are illustrated by FIGS. 3-5. FIG. 3 shows an image of LMP300E after being printed on a Si chip. FIG. 4 shows an image of LMP300E after a glass slide is applied on top of the assembly of FIG. 3. FIG. 5 shows an image of LMP300EAg pressed between two glass slides.

Table 1 below, shows the preparation times for forming different liquid metal pastes. It was observed that liquid metal pastes including silver particles (i.e., LMP300EAg1.0 and LMP300EAg0.5) took far less time to form into a solder paste having a suitable viscosity (e.g., for use with printing). After preparation, the pastes were observed to be pasty, exhibit no phase separation, exhibit good printing ability, and provide good adhesion/wetting on silicon and glass.

TABLE 1

| Name | Composition of Base | Preparation time, min |
|---|---|---|
| LMP300E | 78.6Ga21.4In | 60 min |
| LMP51E | 66.5G/20.5In13.0Sn | 60 min |
| LMP2N | 70Ga20In8Sn2Zn | 60 min |
| LMP300EAg1.0 | 78.6Ga21.4In | 35 min |
| LMP300EAg0.5 | 78.6Ga21.4In | 35 min |

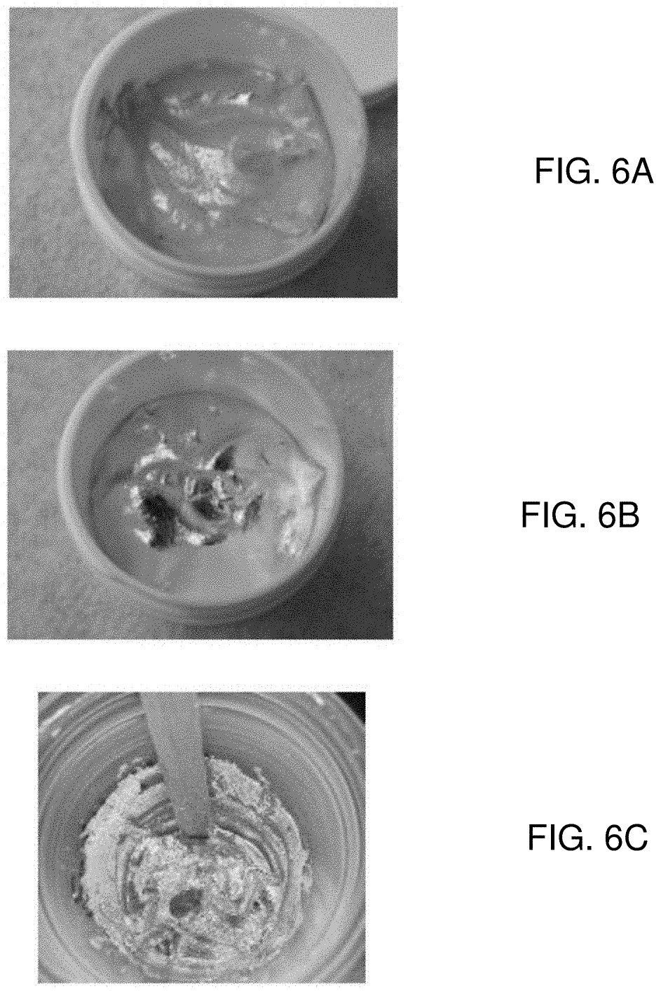

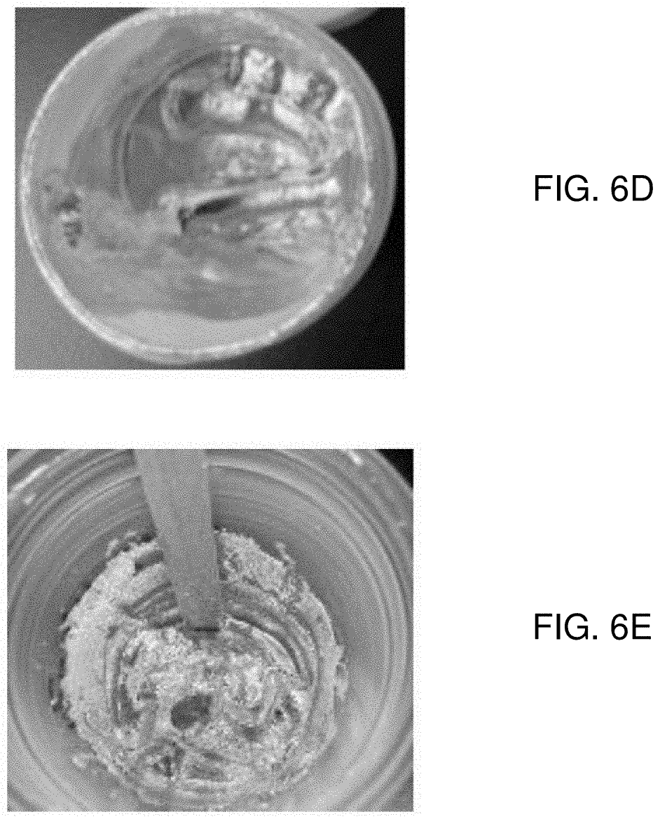

FIGS. 6A-6E show liquid metal pastes formed for LMP300E (FIG. 6A), LMP51E (FIG. 6B), LMP2N (FIG. 6C), LMP300EAg1.0 (FIG. 6D), and LMP300EAg0.5 (FIG. 6E).

Tables 2-4, below, show measured thermal properties of liquid metal pastes that were tested as TIMs, in accordance with some implementations of the disclosure. The table includes parameters such as a controllable BLT/thickness, sample density, thermal impedance (θ), thermal resistance (Rth), and thermal conductivity (K or λ).

TABLE 2
(Thermal properties of LMP300E samples with metal additive)

| | BLT | Density | Rth | θ | K |
|---|---|---|---|---|---|
| Code No. | (μm) | (g/cm³) | (K/W) | (K cm²/W) | (W/m K) |
| 897-57-1, | 69.0116 | 4.92 | 0.0178 | 0.04503 | 8.5550 |
| (78.6Ga21.4In), | | | | | |
| Ag 1 wt %, | | | | | |
| 5-8 micron | | | | | |
| 897-57-1 | 64.6946 | 4.92 | 0.0165 | 0.04503 | 8.6909 |
| 897-57-1 | 62.7807 | 4.92 | 0.0160 | 0.04048 | 8.6550 |
| 897-57-1 | 61.8804 | 4.92 | 0.0132 | 0.03339 | 10.4616 |
| 897-57-1 | 61.9366 | 4.92 | 0.0126 | 0.03187 | 10.9012 |
| 897-57-1 | 105.05 | 4.92 | 0.04 | 0.1012 | 5.61 |
| 897-57-1 | 195.77 | 4.92 | 0.0641 | 0.16217 | 6.72 |
| 897-57-2, | 109.4242 | 4.95 | 0.0465 | 0.11764 | 5.1893 |
| (78.6Ga21.4In), | | | | | |
| Ag 0.5 wt %, | | | | | |
| 5 -8 micron | | | | | |
| 897-57-2 | 103.3135 | 4.95 | 0.0349 | 0.08829 | 6.5340 |
| 897-57-2 | 102.207 | 4.95 | 0.0335 | 0.08475 | 6.732 |
| 897-57-2 | 102.08 | 4.95 | 0.0334 | 0.08450 | 6.740 |
| 897-57-2 | 101.46 | 4.95 | 0.0362 | 0.09158 | 6.18 |
| 897-57-2 | 101.953 | 4.95 | 0.0388 | 0.09816 | 5.796 |
| 897-57-3, | 155.29 | 6.18 | 0.06 | 0.1518 | 5.52 |
| (78.6Ga21.4In) | | | | | |
| Ag, 1 wt %, | | | | | |
| 44 micron | | | | | |
| 897-57-4, | 101.77 | 6.17 | 0.04 | 0.1012 | 6.27 |
| (78.6Ga21.4In) | | | | | |
| Ag, 1 wt %, | | | | | |
| 25 micron | | | | | |

TABLE 3
(Thermal properties of LMP51E samples with metal additive)

| | BLT | Metal | Rth | θ | K |
|---|---|---|---|---|---|
| Code No. | (μm) | (wt %) | (K/W) | (K cm²/W) | (W/m K) |
| 897-71-1 | 118.000 | 1.040 | 0.070 | 0.3171 | 3.920 |
| (Ag, 1 wt %) | | | | | |
| 897-71-2 | 131.000 | 0.990 | 0.040 | 0.1812 | 6.790 |
| (Ag, 1 wt %) | | | | | |
| 897-71-3 | 270.000 | 4.980 | 0.100 | 0.453 | 6.040 |
| (Ag, 5 wt %) | | | | | |
| 897-71-4 | 116.000 | 4.970 | 0.030 | 0.1359 | 8.980 |
| (Ag, 5 wt %) | | | | | |
| 897-71-5 | 149.074 | 1.070 | 0.087 | 0.3941 | 3.785 |
| (Cu, 1 wt %) | | | | | |
| 897-71-6 | 101.000 | 5.000 | 0.070 | 0.3171 | 2.970 |
| (Cu, 5 wt %) | | | | | |
| 897-71-7 | 377.000 | 2.410 | 0.090 | 0.403 | 9.050 |
| (Ag, 2.4 wt %) | | | | | |

TABLE 4
(Thermal properties of additional LMP samples with Ag additive)

| | Ag additive | BLT | Rth | λ |
|---|---|---|---|---|
| Code No. | (wt %) | (μm) | (K/W) | (W/m K) |
| 897-82-7 (300E) | 1 | 178.46 | 0.020 | 19.809 |
| 897-82-6 (51E) | 1 | 213.91 | 0.032 | 14.732 |
| 897-83-3 (2N) | 1 | 134.08 | 0.033 | 8.971 |

In the foregoing examples of Tables 2-4, each row references a different LMP sample for which thermal measurements were taken (e.g., as an average of multiple measurements). In instances where two rows refer to the same “code no.”, this refers to different samples having the sample composition. For example, the first two rows of Table 1 refer to two different samples of 78.6Ga21.4In, Ag 1 wt %, where the Ag particles have the indicated size.

To measure thermal conductivity and resistance of LMPs, a Thermal tester, TIMA 5 (Nanotest, Germany), based on ASTM D5470, was used to directly measure effective thermal conductivity and resistance. As expressed by Equations (1)-(2), below, the effective resistance (Rth_{eff}) includes both the bulk resistance of the TIM Rth_{bulk}, and the contact resistance (Rth₀).

$$R t {h}_{e f f} = R t {h}_{b u l k} + R t {h}_{0} \qquad ( 1 )$$

$${Rth}_{e f f} = \frac{Δ T}{P} \qquad ( 2 )$$

Where P refers to the power/heat delivered through the TIM, and ΔT refers to the temperature difference between a hot and cold Cu meter bar.

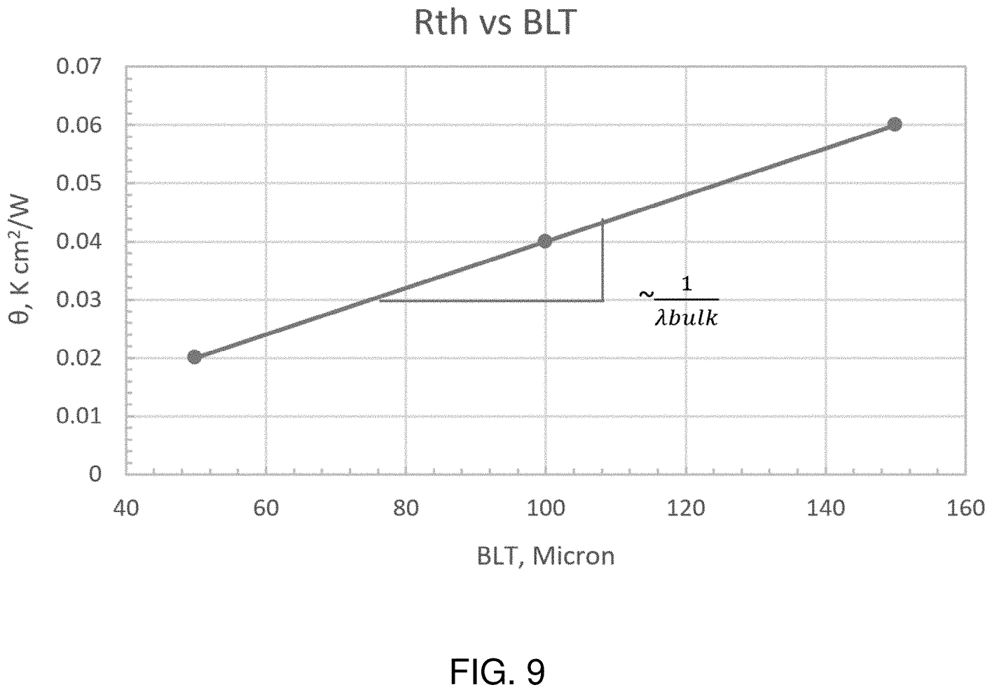

FIG. 9 shows a linear fit plot of thermal impedance (θ) of a sample as a function of sample BLT/thickness. In the plot, λ_{bulk} refers to the bulk thermal conductivity, which can be determined by fitting multiple measurements of thermal impedance for different sample thicknesses/BLTs, and taking the reciprocal of the slope of the fitted line. The zero-thickness intercept of the fitted line can be defined as the interface impedance/resistance. Based on this relationship, Rth_{eff} for a tested TIM can be expressed as Equation (3):

$$R t {h}_{e f f} = \frac{1}{{λ}_{b u l k} * A} * B L T + R t {h}_{0} \qquad ( 3 )$$

Where A is the cross-sectional area of the TIM.

During thermal testing, LMP300EAg1.0 and LMP300EAg0.5 exhibited less leaking of the liquid metal than LMP300E and LMP51E. One surprising and unexpected result that was observed was that the silver containing liquid metal pastes (e.g., LMP300EAg1.0 and LMP300EAg0.5) exhibited improved thermal conductivity as contrasted with the liquid metal paste not containing silver (LMP300E).

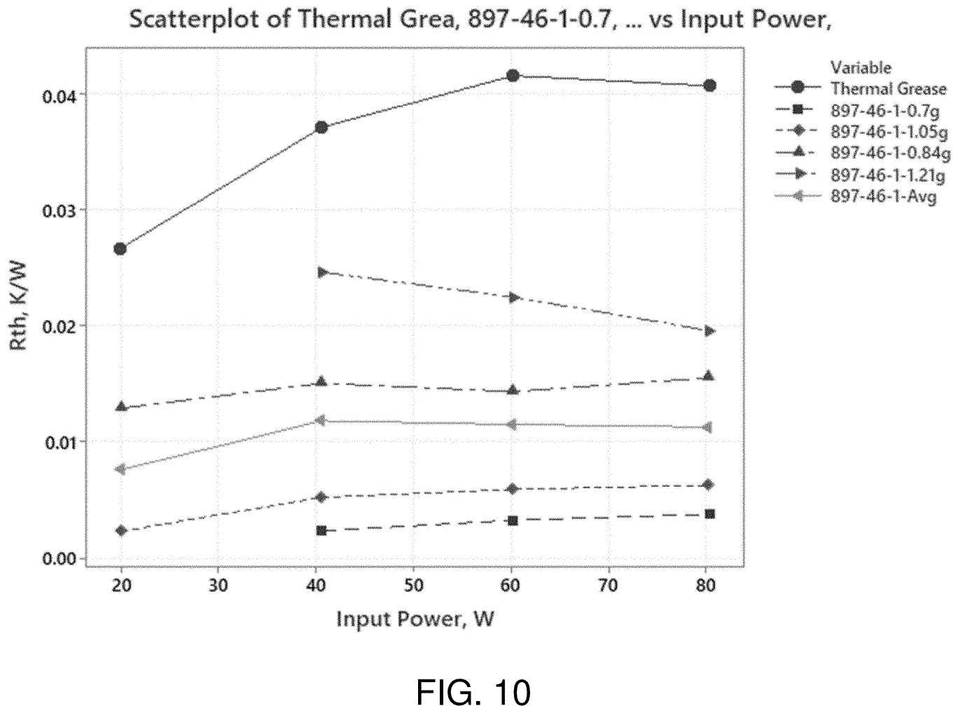

FIG. 10 shows a plot depicting thermal resistance as a function of input power for different TIM samples. As depicted, the measured thermal resistances of the LMP samples in accordance with the disclosure were substantially lower than the measured thermal resistance of the thermal grease sample for different power levels.

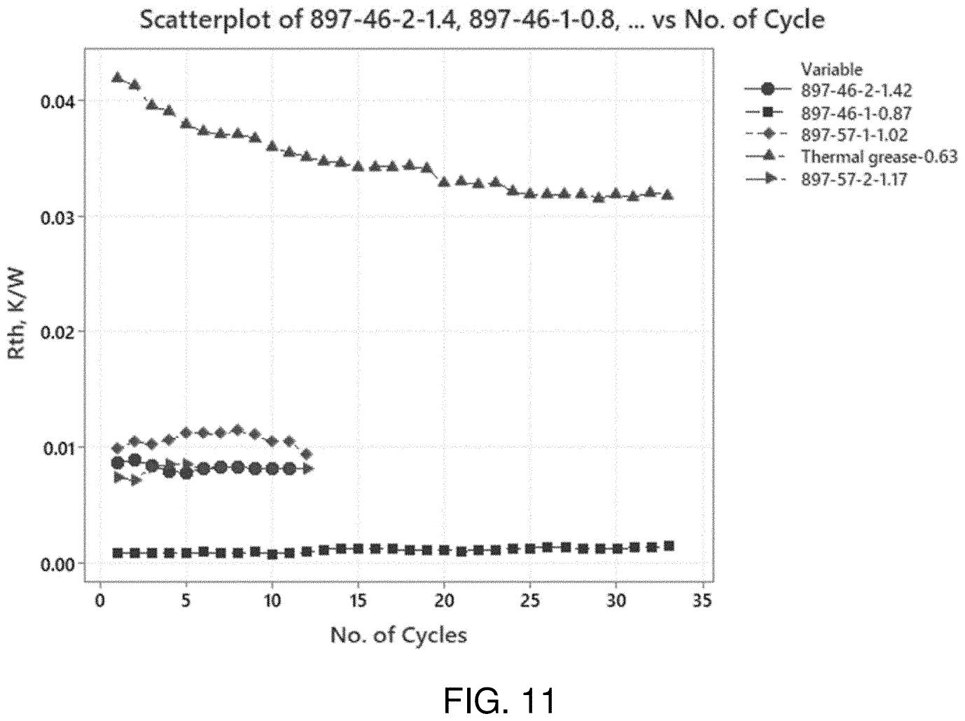

FIG. 11 shows a plot depicting thermal resistance as a function of thermal cycles for different TIM samples. During each cycle, power was supplied for one hour and then turned off for an hour. As depicted, the measured thermal resistances of the LMP samples in accordance with the disclosure were substantially lower than the measured thermal resistance of the thermal grease sample.

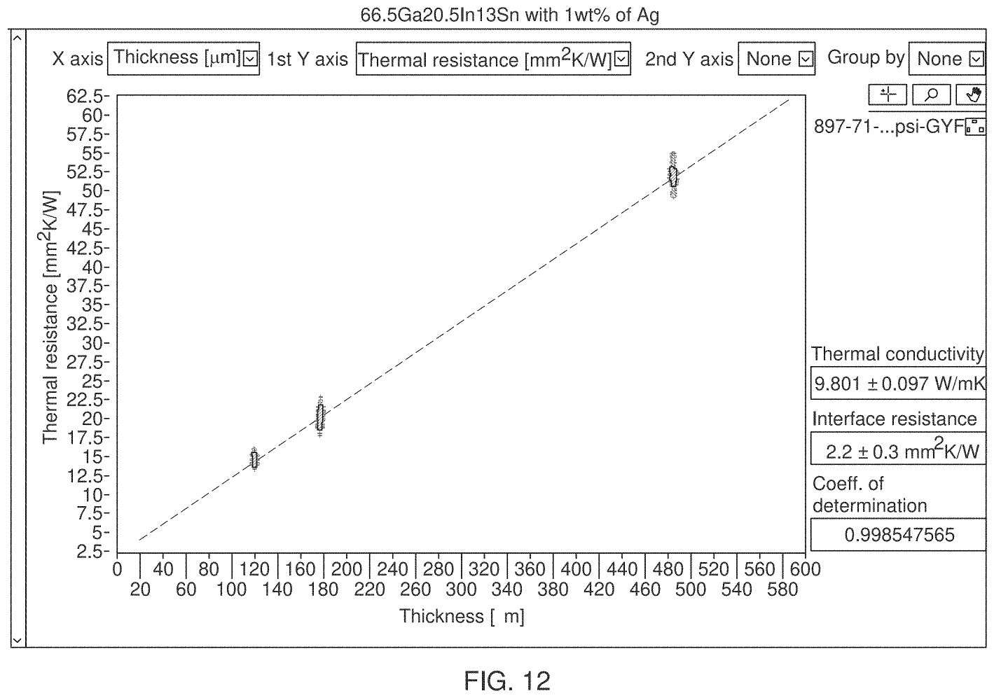

FIG. 12 is a plot showing the measured thermal properties of LMP samples comprised of 66.5Ga20.5In13Sn with 1 wt % of Ag, in accordance with some implementations of the disclosure. In this example, thermal resistance of three samples with different BLT/thickness were measured to calculate the thermal properties of 66.5Ga20.5In13Sn with 1 wt % of Ag. Multiple measurements were taken for each sample to come up with an average. As depicted, the measured thermal conductivity of the sample was 9.801 W/m K, the measured thermal impedance of the sample was 2.2 mm² K/W, and the measured thermal resistance of the sample was 0.0049 K/W.

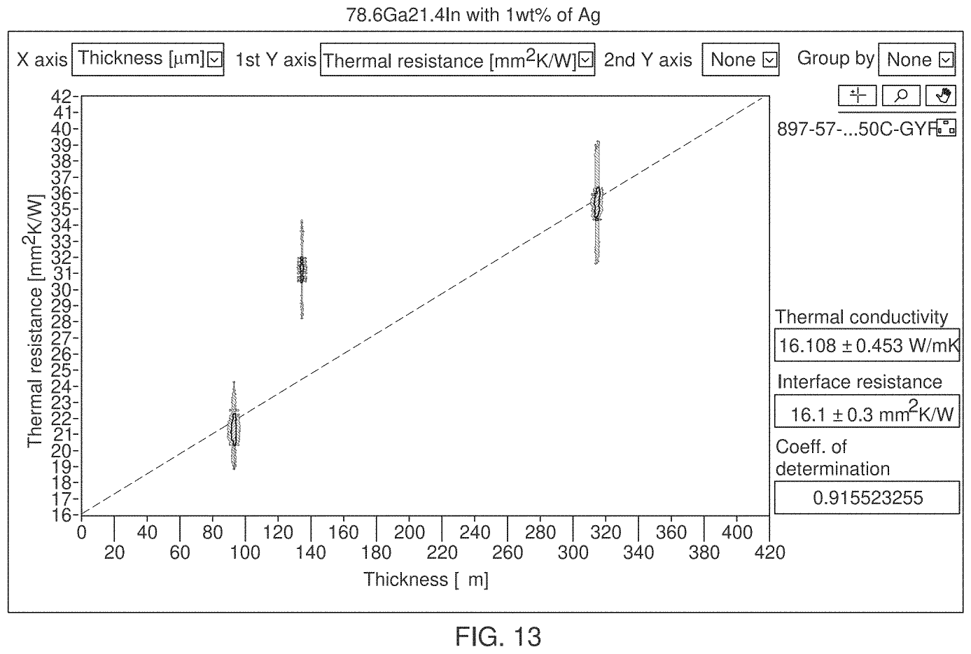

FIG. 13 is a plot showing the measured thermal properties of LMP samples comprised of 78.6Ga21.4In with 1 wt % of Ag, in accordance with some implementations of the disclosure. In this example, thermal resistance of three samples with different BLT/thickness were measured to calculate the thermal properties of 78.6Ga21.4In with 1 wt % of Ag. Multiple measurements were taken for each sample to come up with an average. As depicted, the measured thermal conductivity of the sample was 16.11 W/m K, the measured thermal impedance of the sample was 16.1 mm² K/W, and the measured thermal resistance of the sample was 0.035 K/W.

Although some of the foregoing examples describe a LMP mixture containing a 66.5Ga20.5In13.0Sn liquid metal alloy, the GaInSn LMP embodiments described herein are not necessarily limited to this precise example. For example, in some implementations the LMP can contain a liquid metal alloy consisting of 64 wt % to 69 wt % Ga, 19 wt % to 22 wt % In, and 10 wt % to 16 wt % Sn.

Although some of the foregoing examples describe a LMP mixture containing a 78.6Ga21.4In liquid metal alloy, the GaIn LMP embodiments described herein are not necessarily limited to this precise example. For example, in some implementations the LMP can contain a liquid metal alloy consisting of 75 wt % to 80 wt % Ga, and 20 wt % to 25 wt % In.

Although some of the foregoing examples describe a LMP mixture containing a 70Ga20In8Sn2Zn liquid metal alloy, the GaInSnZn LMP embodiments described herein are not necessarily limited to this precise example. For example, in some implementations the LMP can contain a liquid metal alloy consisting of 67 wt % to 73 wt % Ga, 18 wt % to 22 wt % In, 7 wt % to 9 wt % Sn, and 1 wt % to 3 wt % Zn.

As the foregoing disclosure illustrates, multiple advantages may be realized via the liquid metal pastes describes herein. First, the liquid metal pastes may be formed via an in-situ oxidation process of a liquid gallium or gallium alloy mixed with a low content of metal particles that are coated or not coated with organic compounds. This may provide an easy method to form a microstructure of gallium oxide containing liquid metal such as Ga or GaIn, wherein the metal additive facilitates formation of the liquid metal paste. Second, the metal particle additive may enhance thermal performance of the liquid metal paste prepared from in-situ oxidization of the liquid metal alloy, and it makes a liquid metal TIM suitable for BLT/thickness control. Third, organic capping agents may be applied to the metal particles to help homogeneously disperse the metal particles in the matrix of liquid metal and oxide composition due to Van der Waals forces, and prevent the metal particles from forming IMC with gallium.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

It should be appreciated that all combinations of the foregoing concepts (provided such concepts are not mutually inconsistent) are contemplated as being part of the inventive subject matter disclosed herein. In particular, all combinations of claimed subject matter appearing in this disclosure are contemplated as being part of the inventive subject matter disclosed herein.

What is claimed is:

1. A liquid metal paste configured to be applied as a thermal interface material between electronic components, the liquid metal paste comprising:
92.5 wt % to 99.9 wt % of a liquid gallium or liquid gallium alloy; and
0.1 wt % to 7.5 wt % of a powder of metal particles, the metal particles comprising Ag, Au, Cu, W, Ti, Cr, Ni, Cu or Ni.

2. The liquid metal paste of claim 1, wherein the metal particles comprise Ag, Au, Cu, or Ni.

3. The liquid metal paste of claim 2, comprising:
92.5 wt % to 99.9 wt % of the liquid gallium or liquid gallium alloy; and
0.1 wt % to 5.0 wt % of the powder of the metal particles, the metal particles comprising Ag or Cu particles.

4. The liquid metal paste of claim 3, wherein the metal particles comprise Ag.

5. The liquid metal paste of claim 4, comprising:
92.5 wt % to 99.9 wt % of the liquid gallium or liquid gallium alloy; and
0.1 wt % to 1.5 wt % of the powder of the metal particles, the metal particles consisting of Ag particles.

6. The liquid metal paste of claim 4, consisting of:
98.5 wt % to 99.9 wt % of the liquid gallium or liquid gallium alloy; and
0.1 wt % to 1.5 wt % of the powder of metal particles.

7. The liquid metal paste of claim 3, wherein the liquid gallium alloy is:
64 wt % to 69 wt % Ga, 19 wt % to 22 wt % In, and 10 wt % to 16 wt % Sn;
75 wt % to 80 wt % Ga, and 20 wt % to 25 wt % In; or
67 wt % to 73 wt % Ga, 18 wt % to 22 wt % In, 7 wt % to 9 wt % Sn, and 1 wt % to 3 wt % Zn.

8. The liquid metal paste of claim 7, wherein the liquid gallium alloy is 66.5Ga20.5In13.0Sn, 78.6Ga21.4In, or 70Ga20In8Sn2Zn.

9. The liquid metal paste of claim 1, including 92.5 wt % to 99.9 wt % of the liquid gallium alloy, the liquid gallium alloy comprising GaIn, GaSn, GaInSn, or GaInSnZn.

10. The liquid metal paste 9, wherein the liquid gallium alloy comprises eutectic GaIn or eutectic GaInSn.

11. The liquid metal paste of claim 1, further comprising: an organic compound coating a surface of the metal particles, the organic compound configured to prevent the metal particles from forming an intermetallic compound with the liquid gallium or liquid gallium alloy.

12. The liquid metal paste of claim 11, wherein the organic compound comprises a hydrocarbon compound containing fluoride, ethoxy, methoxy, ketone, or an ester group.

13. The liquid metal paste of claim 11, wherein the organic compound comprises a trimethoxy or trichloro silane containing short chain hydrocarbon (C2 to C6) with fluoride, ethoxy, methoxy, ketone, glycidyloxy, or an ester group.

14. The liquid metal paste of claim 11, wherein the organic compound comprises:

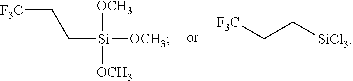

15. The liquid metal paste of claim 11, comprising:
92.5 wt % to 99.8 wt % of the liquid gallium or liquid gallium alloy;
0.1 wt % to 5.0 wt % of the powder of the metal particles, the metal particles comprising Ag or Cu particles; and
the organic compound coating the surface of the Ag or Cu particles, the organic compound configured to prevent the Ag or Cu particles from forming the intermetallic compound with the liquid gallium or liquid gallium alloy.

16. The liquid metal paste of claim 1, wherein the metal particles are spherical particles having a diameter between about 5 μm and 50 μm.

17. An assembly, comprising:
a heat generating device;
a heat transferring device; and
a thermal interface between surfaces of the heat generating device and heat transferring device, wherein the thermal interface is formed by applying a liquid metal paste comprising: 92.5 wt % to 99.9 wt % of a liquid gallium or liquid gallium alloy; 0.1 wt % to 7.5 wt % of a powder of metal particles, the metal particles comprising Ag, Au, Cu, W, Ti, Cr, Ni, Cu or Ni; and optionally, an organic compound coating a surface of the metal particles.

18. The assembly of claim 17, wherein:
the heat generating device is a semiconductor die, and the heat transferring device is a semiconductor package lid; or
the heat generating device is a semiconductor die, and the heat transferring device is a heat sink.

19. A method, comprising:
applying a liquid metal paste between a heat generating device and a heat transferring device to form an assembly having the liquid metal paste in touching relation with a surface of the heat generating device, or in touching relation with a surface of the heat transferring device, the liquid metal paste comprising 92.5 wt % to 99.9 wt % of a liquid gallium or liquid gallium alloy; 0.1 wt % to 7.5 wt % of a powder of metal particles, the metal particles comprising Ag, Au, Cu, W, Ti, Cr, Ni, Cu or Ni; and optionally, an organic compound coating a surface of the metal particles, wherein
the liquid metal paste acts as a thermal interface material configured to transfer heat from the heat generating device to the heat transferring device.

20. The method of claim 19, wherein:
applying the liquid metal paste between the heat generating device and the heat transferring device, comprises: printing the liquid metal paste onto the surface of the heat generating device or the surface of the heat transferring device.
